(19) United States
(12) Patent Application Publication
(10) Pub. No.: US 2026/0150683 A1
(43) Pub. Date: May 28, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Chieh-Ming CHANG, New Taipei City (TW); Ming-Chih YEW, Hsinchu City (TW); Kuo-Chin CHANG, Chiayi City (TW); Kathy Wei YAN, Hsinchu (TW)

(73) Assignee: Taiwan Semiconductor Manufacturing Company, Ltd., Hsinchu (TW)

(21) Appl. No.: 18/959,167

(22) Filed: Nov. 25, 2024

(51) Int. Cl. H01L 23/427; H01L 21/48; H01L 21/56; H01L 23/00; H01L 23/18; H01L 23/498; H01L 25/18

(52) U.S. Cl. CPC H10W 40/73; H10W 70/02; H10W 76/42; H10W 72/29; H10W 74/017; H10W 74/15; H10W 90/00; H10W 90/401; H10W 90/724; H10W 90/734

(57) ABSTRACT

A package structure is provided. The package structure includes a device package component bonded to a package substrate. The package structure includes a ring structure bonded to the package substrate and around the device package component. The package structure also includes a heat pipe disposed between the device package component and the package substrate. The heat pipe laterally extends between the device package component and the ring structure, and the heat pipe is at least partially exposed from the device package component and the ring structure in the normal direction of the package substrate.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1K illustrate cross-sectional views of intermediate steps during a process for fabricating a package structure in accordance with some embodiments.

FIG. 2 illustrates a plan view of the package structure shown in FIG. 1K in accordance with some embodiments.

FIG. 3 illustrates a schematic view of a thermal dissipation system for the package structure shown in FIG. 1K in accordance with some embodiments.

FIG. 4 illustrates a plan view of the package structure in accordance with some embodiments.

FIG. 5A illustrates a plan view of the package structure in accordance with some embodiments.

FIG. 5B illustrates a plan view of the package structure along the line B-B′ shown in FIG. 5A in accordance with some embodiments.

FIG. 6 illustrates a plan view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and methods for fabricating the same are provided. The package structure includes a heat pipe disposed between the device package component and the package substrate. In particular, the heat pipe is thin enough to be installed in the package structure without significantly increasing the size of the package structure. In addition, the heat pipe may connect the device package component and the ring structure, thereby increasing the overall thermal dissipation area (including the surface areas of the device package component, the heat pipe, and the ring structure) and improving the thermal dissipation efficiency of the package structure. The heat pipe may be in contact with the coolant in the immersion cooling system to rapidly dissipate the heat generated by the device package component.

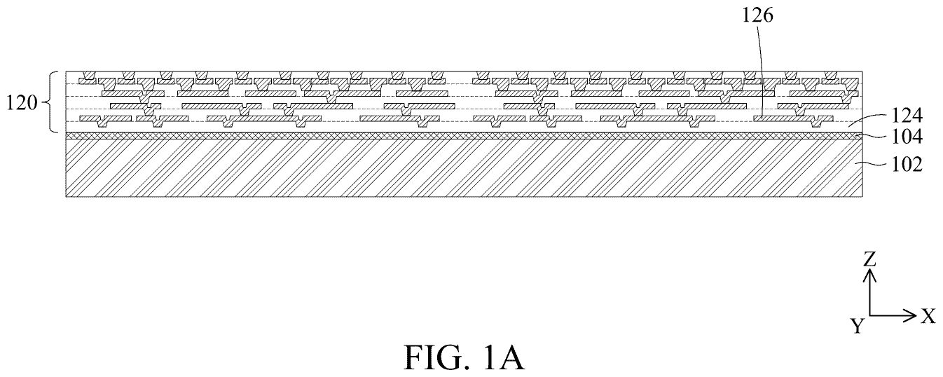

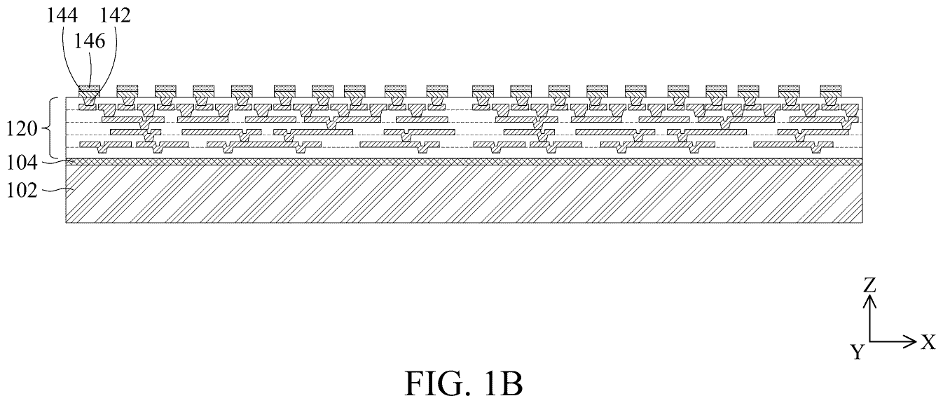

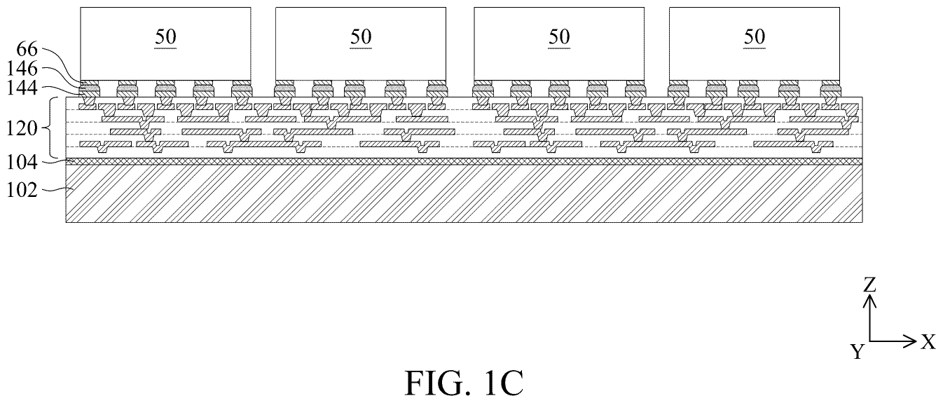

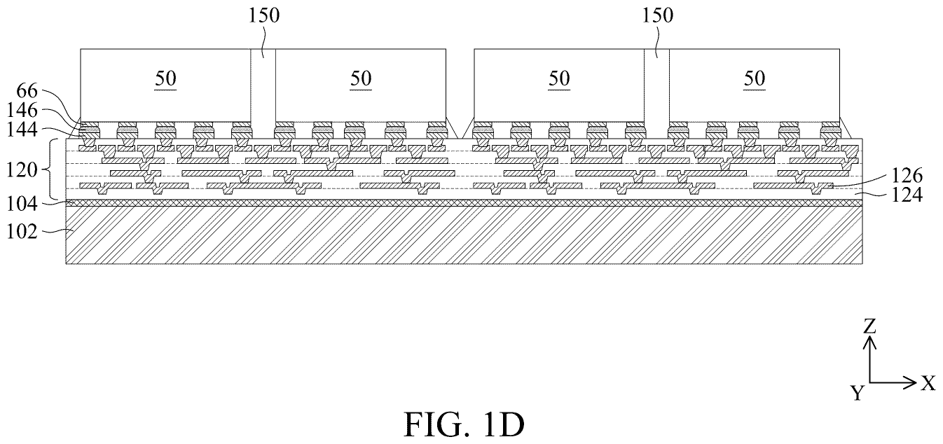

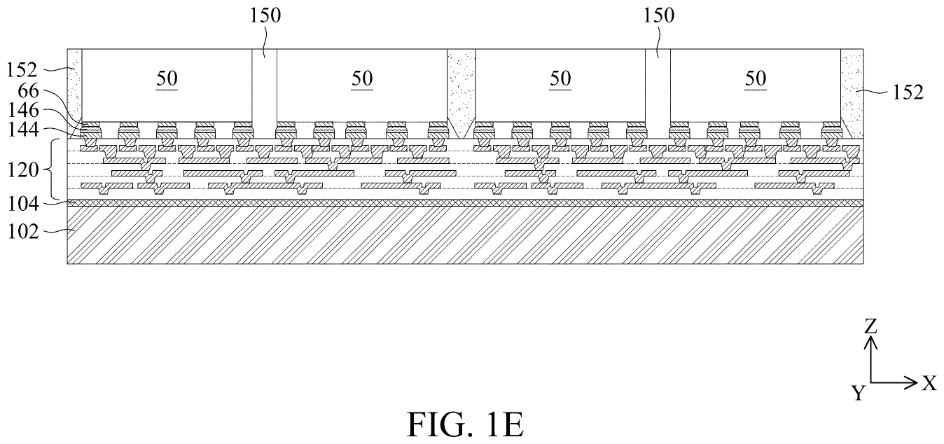

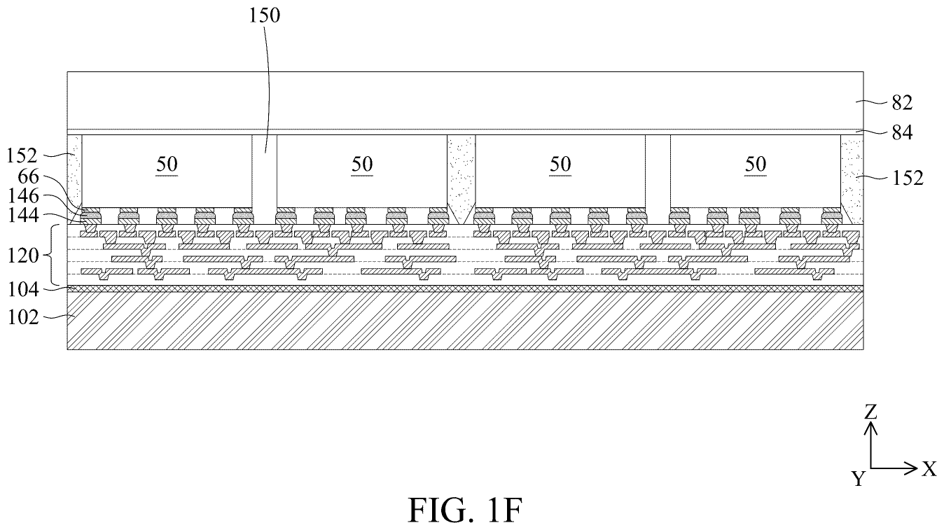

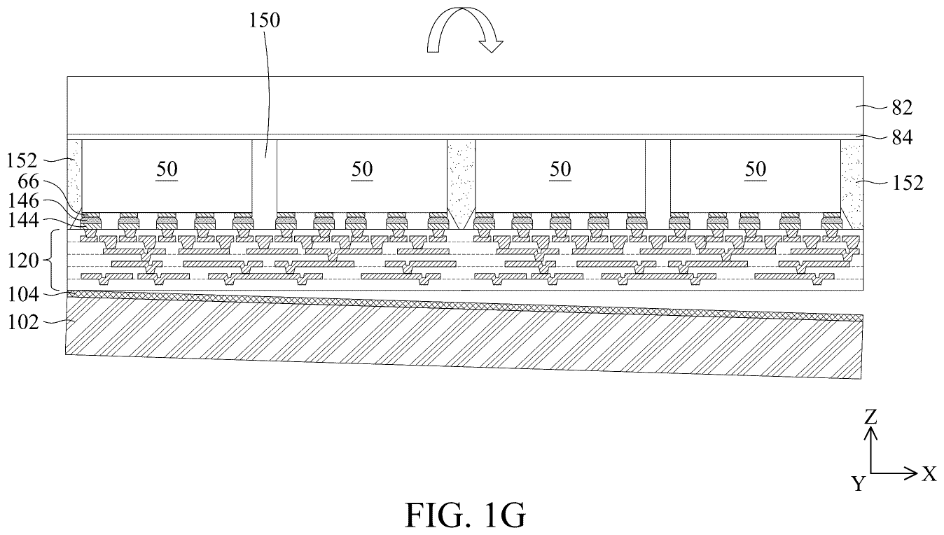

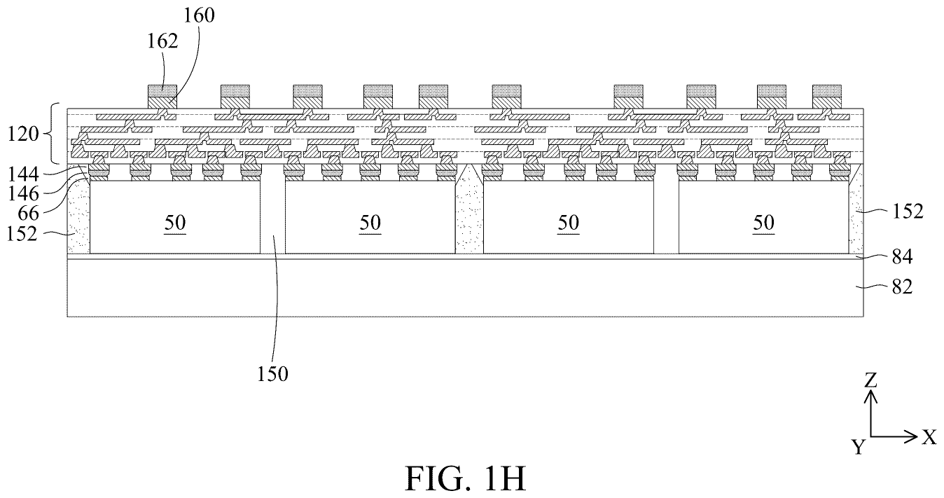

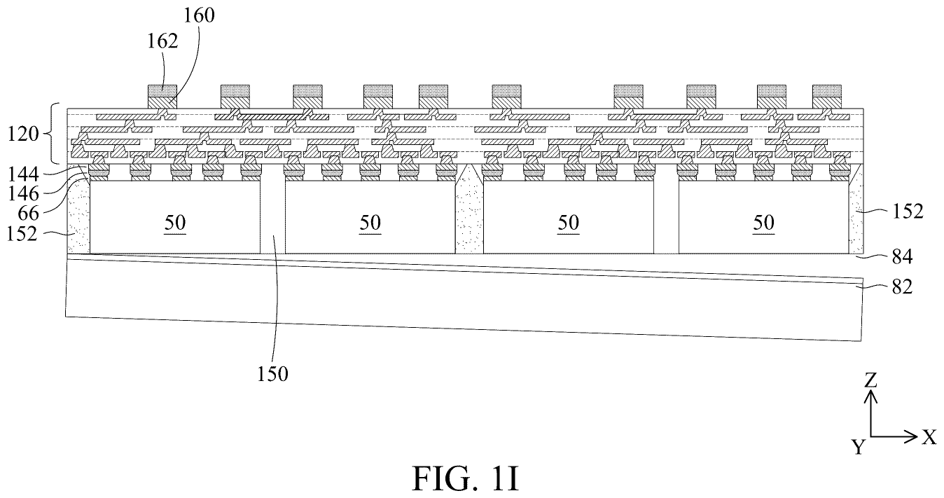

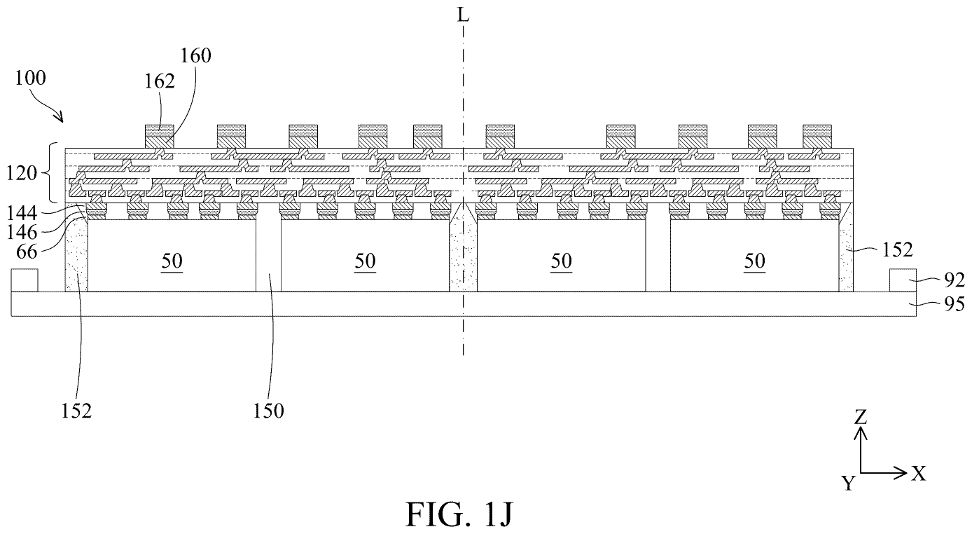

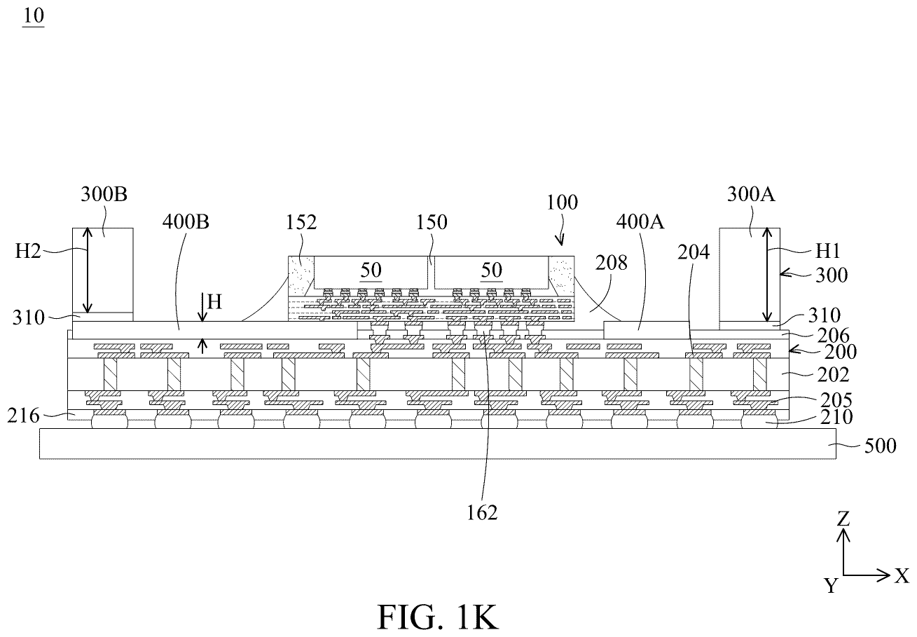

FIGS. 1A through 1K illustrate cross-sectional views of intermediate steps during a process for fabricating a package structure 10 in accordance with some embodiments. In some embodiments, the device dies 50 (for example, referring to FIG. 1E) are packaged to form an integrated circuit package 100. In some embodiments, the integrated circuit packages 100 may also be referred to as integrated fan-out (InFO) packages or device package components. However, the present disclosure is not limited thereto. It should be noted that a plurality of device package components 100 may be formed in a wafer and singulated in the processes. For the sake of clarity and simplicity, one device package component 100 is shown in the present disclosure. In some embodiments, the device package component 100 may be attached to a package substrate 200 to form the package structure 10. The manufacturing process for fabricating the package structure 10 is described in detail below.

As shown in FIG. 1A, a carrier substrate 102 is provided, and a release layer 104 is formed on the carrier substrate 102. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously. In some embodiments, the release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. In some embodiments, the release layer 104 may be dispensed as a liquid and cured, may be a laminate film laminated onto the carrier substrate 102, or may be the like. In some embodiments, the top surface of the release layer 104 is leveled and has a high degree of planarity.

In addition, a redistribution structure 120 is formed over the release layer 104. The redistribution structure 120 is shown as an example having multiple layers of metallization patterns 126 and dielectric layers 124 that are alternatively stacked. In some embodiments, the metallization patterns 126 may also be referred to as redistribution layers or redistribution lines. In some embodiments, the dielectric layer 124 is made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. In some embodiments, the dielectric layers 124 are formed by spin coating, lamination, CVD, the like, or a combination thereof. In some embodiments, the dielectric layer 124 may be patterned by an acceptable process, such as by exposing and developing the dielectric layers 124 to light when the dielectric layers 124 are a photo-sensitive material or by etching using, for example, an anisotropic etch.

In some embodiments, the metallization patterns 126 include conductive elements extending along the major surface of the respective dielectric layers 124 and extending through the respective dielectric layers 124. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching. The combination of the remaining conductive material and underlying portions of the seed layer forms the metallization pattern 126.

As shown in FIG. 1B, conductive vias 142 are then formed in the redistribution structure 120. As an example to form the conductive vias 142, a seed layer is formed in the openings extending through the topmost dielectric layer 124. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer forms the conductive vias 142.

In some embodiments, under-bump metallurgies (UBMs) 144 are formed for external connection to the conductive vias 142. The UBMs 144 may be referred to as pads 144. The UBMs 144 have bump portions on and extending along the major surface of the topmost dielectric layer 124 and physically and electrically couple the conductive vias 142. In some embodiments, the UBMs 144 are formed of the same material as the conductive vias 142. In some embodiments, the UBMs 144 includes alloys such as electroless nickel, electroless palladium, immersion gold, electroless nickel, or the like.

Furthermore, conductive connectors 146 are formed on the UBMs 144. In some embodiments, the conductive connectors 146 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 146 includes a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as a copper pillar) formed by sputtering, printing, electro plating, electroless plating, CVD, or the like. In some embodiments, the metal pillars are solder free and have substantially vertical sidewalls. In some embodiments, a metal cap layer is formed on the top of the metal pillars. In some embodiments, the metal cap layer includes nickel, tin, tin-lead, gold, silver, palladium, indium, nickel-palladium-gold, nickel-gold, the like, or a combination thereof and may be formed by a plating process.

As shown in FIG. 1C, a plurality of device dies 50 are attached to the structure of FIG. 1B. A desired type and quantity of device dies 50 are adopted. In some embodiments, the device dies 50 are referred to as package modules. In the embodiment shown, the device dies 50 are adhered adjacent one another. For example, either of the device dies 50 may be a logic device, such as a central processing unit (CPU), a graphics processing unit (GPU), a system-on-a-chip (SoC), a system-on-integrated-chips (SoIC), a microcontroller, or the like. The other device die 50 may be a memory device, such as a dynamic random access memory (DRAM) die, a static random access memory (SRAM) die, a hybrid memory cube (HMC) module, a high bandwidth memory (HBM) module, or the like. For example, one of the device dies 50 may be a high bandwidth memory (HBM) module with a plurality of DRAM cores, and the other device die 50 may be a SoC die or a SoIC die, but the present disclosure is not limited thereto. In some embodiments, the device dies 50 are formed in the processes of the same technology node, or they are formed in the processes of different technology nodes. For example, one of the device dies 50 may be of a more advanced process node than the other of the device dies 50. The device dies 50 may be different sizes (e.g., different heights and/or surface areas), or they may be the same size (e.g., the same height and/or surface area).

In some embodiments, the device dies 50 are attached to the conductive connectors 146. That is, the die connectors 66 of the device dies 50 are connected to the conductive connectors 146 opposite the UBMs 144. In some embodiments, the conductive connectors 146 are reflowed to attach the device dies 50 to the UBMs 144. The conductive connectors 146 electrically and/or physically couple the redistribution structure 120, including metallization patterns in the redistribution structure 120, to the device dies 50.

In some embodiments, the conductive connectors 146 have an epoxy flux (not shown) formed thereon before they are reflowed with at least some of the epoxy portion of the epoxy flux remaining after the device dies 50 are attached to the redistribution structure 120. This remaining epoxy portion may act as an underfill to reduce stress and protect the joints resulting from reflowing the conductive connectors 146.

As shown in FIG. 1D, an underfill 150 is formed between the device dies 50 and the topmost dielectric layer 124, including between and around the UBMs 144, the conductive connectors 146, and the die connectors 66. In some embodiments, the underfill 150 is formed by a capillary flow process after the device dies 50 are attached or is formed by a suitable deposition method before the device dies 50 are attached. In some embodiments, the underfill 150 is also between the device dies 50. In some embodiments, the underfill 150 may fill the gap between adjacent two of the device dies 50. However, the present disclosure is not limited thereto.

As shown in FIG. 1E, a package molding material 152 is formed around the device dies 50, the conductive connectors 146, and the underfill 150. After formation, the package molding material 152 encapsulates the conductive connectors 146 and the device dies 50. In some embodiments, the package molding material 152 is a molding compound, epoxy, or the like. In some embodiments, the package molding material 152 is applied by compression molding, transfer molding, or the like. In some embodiments, the package molding material 152 is applied in liquid or semi-liquid form and then subsequently cured. In some embodiments, a planarization step may be performed to remove and planarize an upper surface of the package molding material 152. In some embodiments, surfaces of the underfill 150, the package molding material 152, and the device dies 50 are coplanar (within process variation).

As shown in FIG. 1F, a carrier substrate 82 is provided over the device dies 50 and opposite to the carrier substrate 102, and a release layer 84 is formed on the carrier substrate 82. The carrier substrate 82 may be a glass carrier substrate, a ceramic carrier substrate, or the like. In some embodiments, the carrier substrate 82 includes a wafer, such that multiple packages can be supported by the carrier substrate 82 simultaneously. In some embodiments, the release layer 84 is formed of a polymer-based material, which may be removed along with the carrier substrate 82 from the underlying structures in subsequent steps. In some embodiments, the release layer 84 is an epoxy-based thermal-release material, which loses its adhesive property when heated, such as a light-to-heat-conversion (LTHC) release coating. In other embodiments, the release layer 84 may be an ultra-violet (UV) glue, which loses its adhesive property when exposed to UV lights. In some embodiments, the release layer 84 may be dispensed as a liquid and cured, may be a laminate film laminated onto the carrier substrate 82, or may be the like.

As shown in FIG. 1G, a carrier substrate de-bonding is performed to detach (or “de-bond”) the carrier substrate 102 from the redistribution structure 120, e.g., the dielectric layer 124. In accordance with some embodiments, the de-bonding includes projecting a light such as a laser light or an UV light on the release layer 104 so that the release layer 104 decomposes under the heat of the light and the carrier substrate 102 can be removed. The remaining structure is then flipped over and may be supported by the carrier substrate 82.

As shown in FIG. 1H, UBMs 160 are formed for external connection to the redistribution structure 120, e.g., the metallization pattern 126. The UBMs 160 have bump portions on and extending along the major surface of the dielectric layer 124. In some embodiments, the UBMs 160 are formed of the same material as the metallization pattern 126. In addition, conductive connectors 162 are formed on the UBMs 160. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 162 include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 162 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

As shown in FIG. 1I, a carrier substrate de-bonding is performed to detach (or “de-bond”) the carrier substrate 82 from the device dies 50 and the package molding material 152. In accordance with some embodiments, the de-bonding includes projecting a light such as a laser light or an UV light on the release layer 84 so that the release layer 84 decomposes under the heat of the light and the carrier substrate 82 can be removed.

As shown in FIG. 1J, after the carrier substrate 82 is removed, the remaining structure is then placed on a tape 95, which may be supported by the frame 92. In some embodiments, a singulation process is performed along scribe lines L to form a plurality of device package components 100. The singulation process may be a mechanical saw process, although the present disclosure is not limited thereto. Accordingly, the device package component 100 is formed.

As shown in FIG. 1K, the device package component 100 may be mounted on the package substrate 200 using the conductive connectors 162. The package substrate 200 is, in some embodiments, based on a substrate core 202 such as a fiberglass reinforced resin core. One example material of the substrate core 202 is fiberglass resin. Alternatives for the core material include bismaleimide-triazine (BT) resin, or alternatively, other PCB materials or films. Build up films or other laminates may be used for package substrate 200. In some embodiments, the package substrate 200 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 200 is a semiconductor-on-insulator (SOI) substrate. Generally, an SOI substrate includes a layer of a semiconductor material such as epitaxial silicon, germanium, silicon germanium, SOI, SGOI, or combinations thereof.

In some embodiments, the package substrate 200 includes interconnect structures 204 and 205 that are located on opposite sides of the substrate core 202. The conductive connectors 162 electrically and/or physically couple the package substrate 200, including the interconnect structure 204 and the substrate core 202, to the device package component 100. In some embodiments, a solder resist 206 is formed on the package substrate 200. In some embodiments, the conductive connectors 162 are disposed in openings in the solder resist 206 over the interconnect structure 204 to be electrically and mechanically coupled to the substrate core 202. In some embodiments, the solder resist 206 is used to protect areas of the package substrate 200 from external damage.

In some embodiments, the package substrate 200 includes bump structures 210 over the interconnect structure 205. The interconnect structure 205 may be made of conductive material and electrically connected to the device package component 100 and the bump structures 210. As a result, external connection can be formed for the device package component 100 via the package substrate 200. In some embodiments, the bump structures 210 may be conductive ball structures (such as ball grid array (BGA)), conductive pillar structures, or conductive paste structures that are mounted on and electrically coupled to the package substrate 200 in the bonding process. Similarly, a solder resist 216 is formed on the package substrate 200. In some embodiments, the bump structures 210 are disposed in openings in the solder resist 216 over the interconnect structure 205 to be electrically and mechanically coupled to the substrate core 202. In some embodiments, the solder resist 216 is used to protect areas of the package substrate 200 from external damage. In some embodiments, the bump structures 210 may be bonded to a printed circuit board (PCB) 500. However, the present disclosure is not limited thereto.

In some embodiments, the conductive connectors 162 are reflowed to attach the device package component 100 to the package substrate 200. The conductive connectors 162 electrically and/or physically couple the metallization layers in the package substrate 200, to the device package component 100. In some embodiments, the conductive connectors 162 have an epoxy flux (not shown) formed thereon before they are reflowed with at least some of the epoxy portion of the epoxy flux remaining after the device package component 100 is attached to the package substrate 200. This remaining epoxy portion may act as an underfill to reduce stress and protect the joints resulting from reflowing the conductive connectors 162. In some embodiments, an underfill 208 is formed between the device package component 100 and the package substrate 200 and surrounding the conductive connectors 162. In some embodiments, the underfill 208 is formed by a capillary flow process after the device package component 100 is attached or may be formed by a suitable deposition method before the device package component 100 is attached.

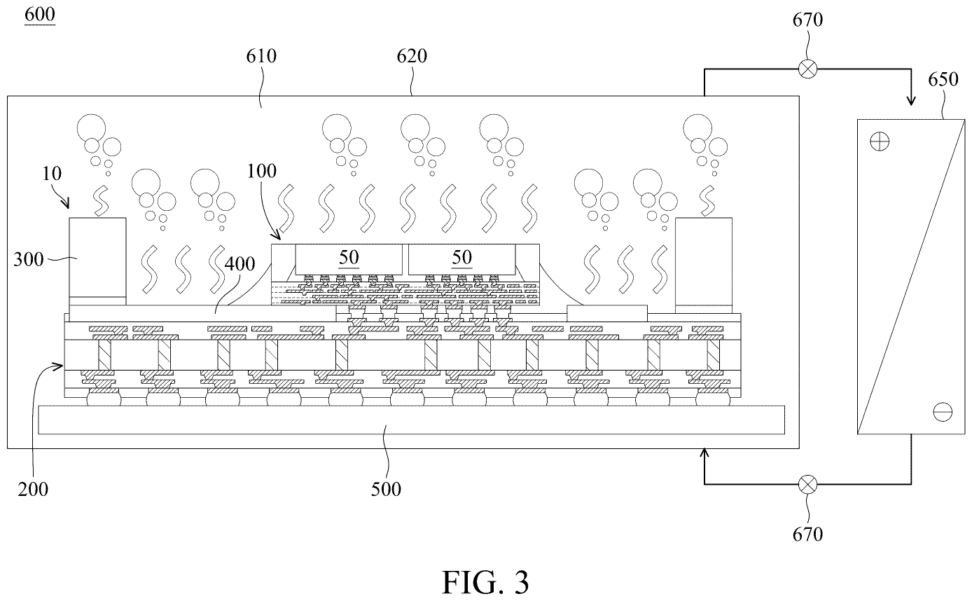

Furthermore, a plurality of heat pipes 400A and 400B with different lengths are disposed over the package substrate 200, and a ring structure 300 is mounted on the package substrate 200 to form a package structure 10. In some embodiments, the heat pipes 400A and 400B laterally extend between the device package component 100 and the ring structure 300, and at least partially exposed from the device package component 100 and the ring structure 300. In particular, a portion of the heat pipe 400B extends below the device package component 100 and below the ring structure 300, and is sandwiched between the package substrate 200 and the device package component 100. Accordingly, the heat generated by the device package component 100 can be dissipated to the ring structure 300 via the heat pipe 400B, thereby increasing the overall thermal dissipation area (including the surface areas of the device package component 100, the heat pipes 400A and 400B, and the ring structure 300) and improving the thermal dissipation efficiency of the package structure 10. It should be noted that although the heat pipe 400A may not be in contact with the device package component 100 and the ring structure 300, the heat pipe 400A may also help to spread out the heat generated by the device package component 100 to the environment. For example, the heat pipe 400A may be in contact with the coolant (for example, referring to FIG. 3) supplied to the package structure 10, and therefore helps to dissipate the heat to the coolant.

In some embodiments, the heat pipes 400A and 400B are partially embedded in the underfill 208 and spaced apart from the conductive connectors 162 of the device package component 100. As a result, the heat pipes 400A and 400B would not interfere with the electrical connection between the device package component 100 and the package substrate 200. In some embodiments, the distance between the heat pipe 400A or 400B and the adjacent one of the conductive connectors 162 is greater than the pitch of the conductive connectors 162. For example, the distance between the heat pipe 400B, which extends below the device package component 100, and the adjacent one of the conductive connectors 162 may be in a range from about 100 μm to about 300 μm, such as about 150 μm. However, the present disclosure is not limited thereto. Accordingly, sufficient space may be provided to reduce the risk of current leakage between the conductive connectors 162 and the heat pipe 400B.

In some embodiments, each of the heat pipes 400A and 400B includes a vapor flow channel that is defined by a heat pipe wall (not individually shown), and a vaporizable working fluid (such as water) may be sealed within the heat pipes 400A and 400B, e.g., the vapor flow channel thereof. It some embodiments, the heat pipe wall is made of metal, such as copper (Cu) or any other suitable material. For example, the vaporizable working fluid absorbs the heat generated by the device package component 100 and evaporates, and the vapor of the working fluid would perform heat exchange with the environment. Accordingly, the heat would be transferred to the environment, and then the vapor of the working fluid condenses into liquid form. Such process is repeated in the heat pipes 400A and 400B to dissipate the heat generated by the device package component 100. As set forth above, the heat pipes 400A and 400B may facilitate the thermal dissipation of the package structure 10. In some embodiments, a wick structure may be formed in the vapor flow channel and on the heat pipe wall of the heat pipes 400A and 400B. In this way, the vaporization and condensation of the working fluid in the heat pipes 400A and 400B can be facilitated, thereby improving the thermal dissipation of the package structure 10. In some embodiments, a thickness H of the heat pipes 400A and 400B is less than about 0.3 mm in the normal direction (for example, the Z direction) of the package substrate 200. Such thin heat pipes 400A and 400B may be installed in the package structure 10 without significantly increasing the size of the package structure 10.

In some embodiments, the ring structure 300 includes a first portion 300A and a second portion 300B that is connected to the first portion 300A. In some embodiments, the second portion 300B is opposite to the first portion 300A. For example, the heat pipe 400B is partially embedded below the second portion 300B of the ring structure 300, and therefore the height H2 of the second portion 300B of the ring structure 300 is less than the height H1 of the first portion 300A of the ring structure 300 in the normal direction (for example, the Z direction) of the package substrate 200. In some embodiments, the ring structure 300 is bonded to the package substrate 200 via an adhesive film 310, and the adhesive film 310 is in contact with the heat pipe 400B. However, the present disclosure is not limited thereto. For example, the heat pipes 400A and 400B are disposed over the package substrate 200 first. Then, the device package component 100 is bonded to the package substrate 200, and the ring structure 300 is bonded to the package substrate 200 and around the device package component 100.

To be more specific, when the device package component 100 is bonded to the package substrate 200, the device package component 100 covers a portion of the heat pipe 400B on the package substrate 200. Also, when the ring structure 300 is bonded to the package substrate 200, the ring structure 300 covers another portion of the heat pipe 400B on the package substrate 200. In some embodiments, the adhesive film 310 is dispensed over the package substrate 200 before the ring structure 300 is bonded to the package substrate 200, and the adhesive film 310 is in contact with the heat pipe 400B. In some embodiments, the second portion 300B having the height H2 is aligned with the heat pipe 400B. As a result, a portion of the heat pipe 400B is disposed between the package substrate 200 and the device package component 100, and configured to dissipate the heat from the device package component 100 to the environment.

In some embodiments, the heat pipes 400A and 400B extend in a direction (for example, the horizontal direction) that is perpendicular to the normal direction of the package substrate 200. It should be noted that for the sake of brevity, the heat pipes 400A and 400B (and other heat pipes, if present) may be collectively referred to as the heat pipes 400 as follows. It should be noted that the package structure 10 in the present embodiment merely serves as an example, those skilled in the art should be able to realize that additional components may be added to the package structure 10 to achieve desired functions. Every possible configuration of the package structure 10 is included within the scope of the present disclosure.

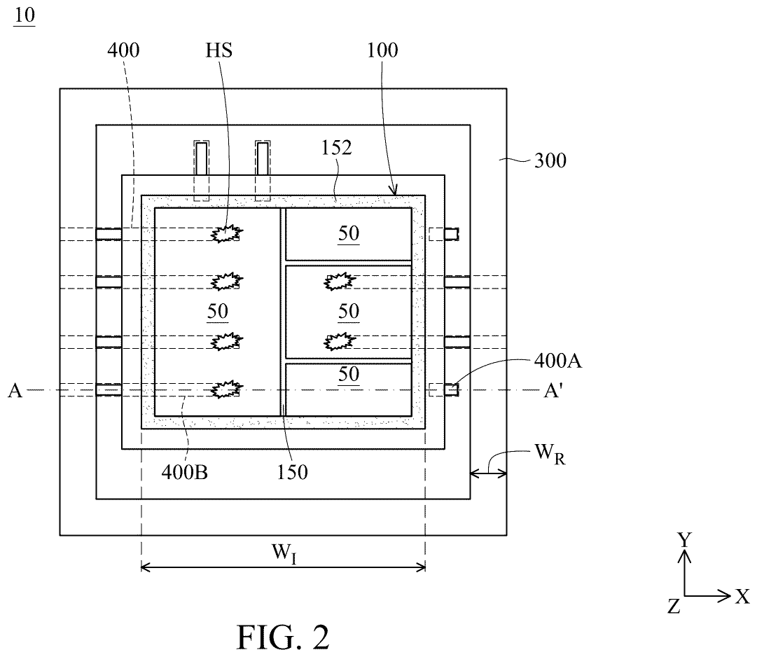

FIG. 2 illustrates a plan view of the package structure shown in FIG. 1K in accordance with some embodiments. It should be noted that for example, FIG. 1K is illustrated along the line A-A′ shown in FIG. 2, but the present disclosure is not limited thereto. As shown in FIG. 2, the device package component 100 includes a plurality of device dies 50, which are encapsulated by the package molding material 152. In some embodiments, the heat pipe 400B extends directly below the adjacent device die 50 of the device package component 100. In particular, the heat pipe 400B and other heat pipes 400 may extend to a position corresponding to the hot spots HS of the device dies 50 (such as high power-consumption dies, e.g., SoC dies, SoIC dies, etc.). As a result, the heat pipes 400 may effectively dissipate the heat from the hot spots HS of the device dies 50, improving the performance and reliability of the package structure 10. In some embodiments, the heat pipe 400A is separated from the adjacent device die 50 (such as low power-consumption dies, e.g. DRAM dies, HBM dies, dummy dies, etc.) in the plan view. The arrangement (for example, locations, lengths, distribution density, etc.) of the heat pipes 400 may be adjustable depends upon the performance of the device die 50, and any configuration of the heat pipes 400 should be included within the scope of the present disclosure.

In some embodiments, the device package component 100 has a width W_{I}, and each side of the ring structure 300 has a width W_{R}. For example, the widths W_{I} and W_{R} may be measured in a horizontal direction (for example, the X direction) that is perpendicular to the normal direction of the package substrate 200. In some embodiments, the heat pipe 400A is spaced apart from the device package component 100 and the ring structure 300 in the plan view, and the heat pipe 400B partially overlaps the device package component 100 and the ring structure 300 in the plan view. The length of the overlapped portion of the heat pipe 400B under the device package component 100 is less than or equal to half (that is, 50% of) the width W_{I} of the device package component 100. Accordingly, the heat pipe 400B would not interfere with the connection between the device package component 100 and the package substrate 200 via the conductive connectors 162. In some embodiments, the length of the overlapped portion of the heat pipe 400B under the ring structure 300 is less than or equal to the width W_{R} of the ring structure 300.

FIG. 3 illustrates a schematic view of an immersion cooling system 600 for the package structure 10 shown in FIG. 1K in accordance with some embodiments. As shown in FIG. 3, the immersion cooling system 600 may include a cooling tank 620 that may be configured to store the coolant 610 and the package structure 10. For example, the coolant 610 may include mineral oil, silicone fluid, or other suitable compounds, but the present disclosure is not limited thereto. The package structure 10 may be disposed in the cooling tank 620 and completely immersed in the coolant 610. In particular, the heat pipes 400 of the package structure 10 are exposed and in contact with the coolant 610, thereby increasing the overall thermal dissipation area (including the surface areas of the device package component 100, the heat pipes 400A and 400B, and the ring structure 300), as discussed above. As a result, the heat generated by the package structure 10 can be taken away by the flow of the coolant 610, so that the package structure 10 can be kept at an appropriate working temperature, and therefore the failure risk of the package structure 10 due to overheat can be reduced.

In some embodiments, the immersion cooling system 600 further includes a heat exchanger 650, and the heat exchanger 650 is communicated with the cooling tank 620 via pumps 670. In some embodiments, one of the pumps 670 outputs power so that the coolant 610 in the cooling tank 620 flows into the heat exchanger 650. In particular, the coolant 610 is cooled down in the heat exchanger 650. After the coolant 610 completes the heat exchange in the heat exchanger 650, the power output by the other of the pumps 670 may make the coolant 610 in the heat exchanger 650 to flow into the cooling tank 620 and flow through the package structure 10. With the circulation of the coolant 610 in the immersion cooling system 600, the heat generated by the package structure 10 may be dissipated more rapidly, thereby keeping the package structure 10 under an appropriate working temperature.

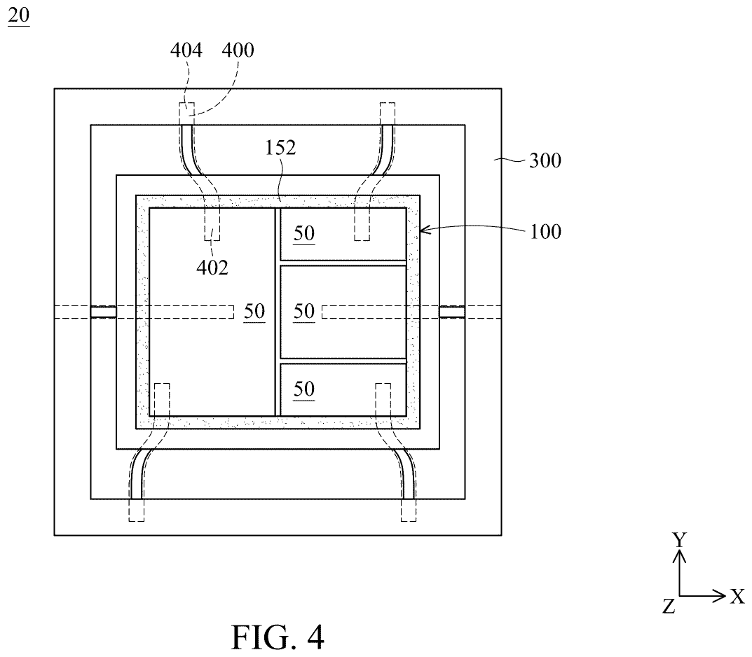

FIG. 4 illustrates a plan view of the package structure 20 in accordance with some embodiments. It should be noted that the package structure 20 may include elements or portions that are the same as or similar to those of the package structure 10 shown in FIG. 2. These elements or portions will be denoted by the same or similar numerals, and will not be discussed in detail below for the sake of brevity. As shown in FIG. 4, each of the heat pipes 400 includes a first end 402 and a second end 404 that is opposite to the first end 402. In particular, the first end 402 is closer to the device package component 100 than the second end 404. Otherwise, the second end 404 is closer to the ring structure 300 than the first end 402. In the present embodiments, some of the heat pipes 400 are curved (i.e., non-linear) in the plan view. That is, the first end 402 is misaligned with the second end 404 on one side of the package structure 20. Such configuration of the heat pipes 400 may provide more flexibility to arrange the conductive connectors 162 of the device package component 100, and various functions of the device package component 100 can be achieved.

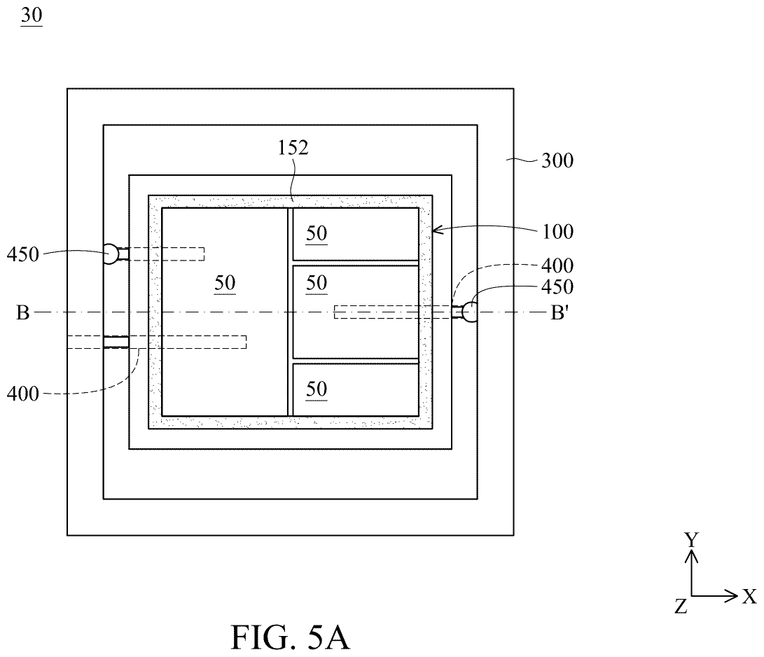

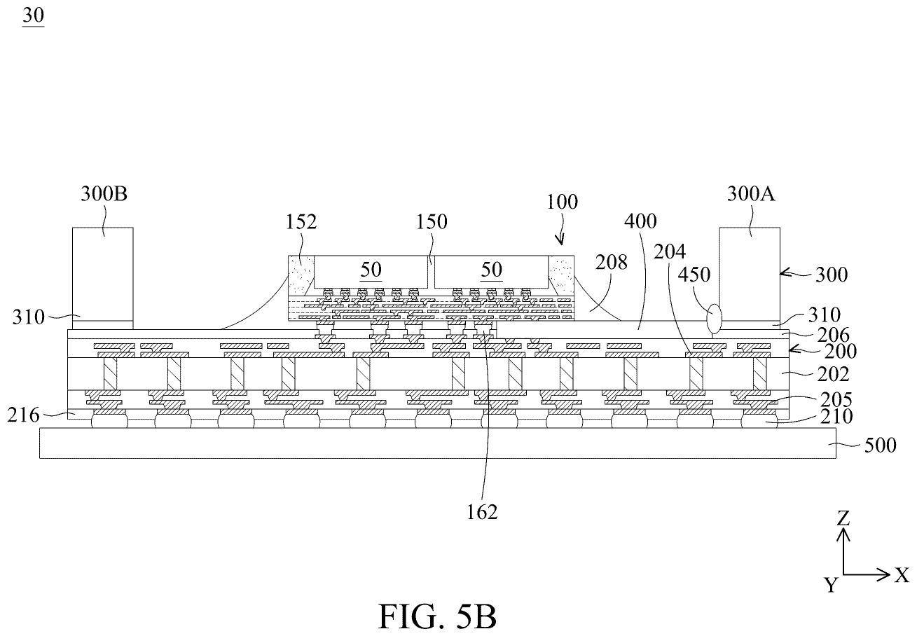

FIG. 5A illustrates a plan view of the package structure 30 in accordance with some embodiments. FIG. 5B illustrates a plan view of the package structure along the line B-B′ shown in FIG. 5A in accordance with some embodiments. It should be noted that the package structure 30 may include elements or portions that are the same as or similar to those of the package structure 10 shown in FIGS. 1K and 2. These elements or portions will be denoted by the same or similar numerals, and will not be discussed in detail below for the sake of brevity. As shown in FIGS. 5A and 5B, some of the heat pipes 400 are connected to the ring structure 300 via a thermal interface material (TIM) 450. To be more specific, the thermal interface material 450 is in contact with the ring structure 300 and the individual heat pipe 400. Accordingly, the heat generated by the device package component 100 can be dissipated to the ring structure 300 via the heat pipes 400 and the thermal interface material 450. In this way, the heat pipe 400 may not be embedded below the ring structure 300, thereby reducing the cost and difficulty of forming the package structure 30.

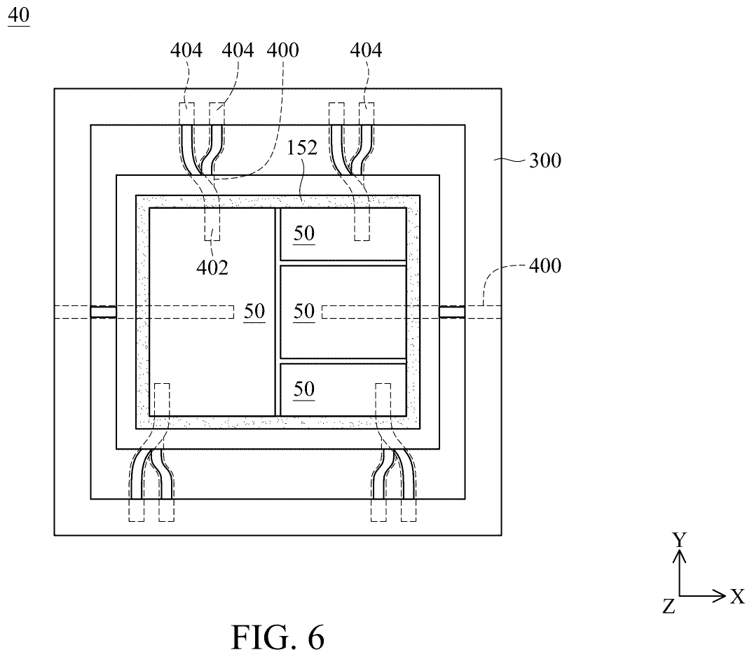

FIG. 6 illustrates a plan view of the package structure 40 in accordance with some embodiments. It should be noted that the package structure 40 may include elements or portions that are the same as or similar to those of the package structure 10 shown in FIG. 2. These elements or portions will be denoted by the same or similar numerals, and will not be discussed in detail below for the sake of brevity. As shown in FIG. 6, some of the heat pipes 400 each includes a first end 402 and a plurality of second ends 404 that are connected to the first end 402. Similarly, the first end 402 is closer to the device package component 100 than the second ends 404. Otherwise, the second ends 404 are closer to the ring structure 300 than the first end 402. Such configuration of the heat pipes 400 may help to spread out the heat from the device package component 100 to the ring structure 300, thereby improving thermal dissipation efficiency of the package structure 40.

Embodiments of package structures and methods for fabricating the same are provided. The package structure includes a heat pipe disposed between the device package component and the package substrate. In particular, the heat pipe is thin enough to be installed in the package structure without significantly increasing the size of the package structure. In addition, the heat pipe may connect the device package component and the ring structure, thereby increasing the overall thermal dissipation area (including the surface areas of the device package component, the heat pipe, and the ring structure) and improving the thermal dissipation efficiency of the package structure. The heat pipe may be in contact with the coolant in the immersion cooling system to rapidly dissipate the heat generated by the device package component. Furthermore, the ring structure may include a portion with the lower height and the conductive connectors are specifically arranged so as to accommodate the heat pipe, and therefore the heat pipe may not interfere with the operation of the package structure. Moreover, the arrangement (for example, locations, lengths, distribution density, etc.) of the heat pipes may be adjustable depends upon the performance of the device dies in the device package component.

In some embodiments, a package structure is provided. The package structure includes a device package component bonded to a package substrate. The package structure includes a ring structure bonded to the package substrate and around the device package component. The package structure also includes a heat pipe disposed between the device package component and the package substrate. The heat pipe laterally extends between the device package component and the ring structure, and the heat pipe is at least partially exposed from the device package component and the ring structure in the normal direction of the package substrate.

In some embodiments, a package structure is provided. The package structure includes a device package component bonded to a package substrate. The package structure includes a ring structure bonded to the package substrate and around the device package component. The ring structure includes a first portion and a second portion opposite to the first portion. The package structure also includes a heat pipe disposed over the package substrate. The heat pipe is disposed between the device package component and the ring structure, the heat pipe is partially embedded below the second portion of the ring structure, and the height of the second portion of the ring structure is less than the height of the first portion of the ring structure in the normal direction of the package substrate.

In some embodiments, a method for fabricating a package structure is provided. The method includes disposing a plurality of heat pipes over a package substrate. The method includes bonding a device package component to the package substrate. The method also includes bonding a ring structure to the package substrate and around the device package component. A portion of the heat pipes is sandwiched between the package substrate and the device package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a device package component bonded to a package substrate;
a ring structure bonded to the package substrate and around the device package component; and
a heat pipe disposed between the device package component and the package substrate, wherein the heat pipe laterally extends between the device package component and the ring structure, and the heat pipe is at least partially exposed from the device package component and the ring structure in a normal direction of the package substrate.

2. The package structure as claimed in claim 1, further comprising an underfill formed between the device package component and the package substrate, wherein the underfill surrounds a plurality of conductive connectors of the device package component, and the heat pipe is partially embedded in the underfill.

3. The package structure as claimed in claim 2, wherein the heat pipe is spaced apart from the conductive connectors of the device package component.

4. The package structure as claimed in claim 3, wherein a distance between the heat pipe and one of the conductive connectors is greater than a pitch of the conductive connectors.

5. The package structure as claimed in claim 1, wherein the heat pipe extends directly below a first device die of the device package component.

6. The package structure as claimed in claim 5, wherein the device package component further comprises a second device die adjacent to the first device die, and the heat pipe is separated from the second device die in a plan view.

7. The package structure as claimed in claim 1, further comprising a thermal interface material disposed between the ring structure and the heat pipe.

8. The package structure as claimed in claim 6, wherein the thermal interface material is in contact with the ring structure and the heat pipe.

9. The package structure as claimed in claim 1, wherein the heat pipe is curved in a plan view.

10. The package structure as claimed in claim 1, wherein the heat pipe comprises a first end and a plurality of second ends connected to the first end, and the second ends are closer to the ring structure than the first end.

11. The package structure as claimed in claim 1, wherein a thickness of the heat pipe is less than about 0.3 mm in the normal direction of the package substrate.

12. A package structure, comprising:
a device package component bonded to a package substrate;
a ring structure bonded to the package substrate and around the device package component, wherein the ring structure comprises a first portion and a second portion opposite to the first portion; and
a heat pipe disposed over the package substrate, wherein the heat pipe is disposed between the device package component and the ring structure, the heat pipe is partially embedded below the second portion of the ring structure, and a height of the second portion of the ring structure is less than a height of the first portion of the ring structure in a normal direction of the package substrate.

13. The package structure as claimed in claim 12, wherein the ring structure is bonded to the package substrate via an adhesive film, and the adhesive film is in contact with the heat pipe.

14. The package structure as claimed in claim 12, wherein the device package component is bonded to the package substrate via a plurality of conductive connectors, and the conductive connectors are spaced apart from the heat pipe when viewed in the normal direction of the package substrate.

15. A method for fabricating a package structure, comprising:
disposing a plurality of heat pipes over a package substrate;
bonding a device package component to the package substrate; and
bonding a ring structure to the package substrate and around the device package component, wherein a portion of the heat pipes is sandwiched between the package substrate and the device package component.

16. The method as claimed in claim 15, wherein bonding the device package component to the package substrate further comprises covering a portion of the heat pipes on the package substrate.

17. The method as claimed in claim 15, wherein bonding the ring structure to the package substrate further comprises covering a portion of the heat pipes on the package substrate.

18. The method as claimed in claim 15, further comprising:
dispensing an adhesive film over the package substrate before bonding the ring structure to the package substrate, wherein the adhesive film is in contact with one of the heat pipes and the ring structure after the ring structure is bonded to the package substrate.

19. The method as claimed in claim 15, wherein bonding the ring structure to the package substrate further comprises aligning a portion of the ring structure with one of the heat pipes, a height of the portion of the ring structure is less than a height of a remaining portion of the ring structure.

20. The method as claimed in claim 15, wherein disposing the heat pipes over the package substrate further comprises disposing the heat pipes with different lengths.
